(19) United States
(12) Patent Application Publication
(10) Pub. No.: US 2026/0297804 A1
(43) Pub. Date: Oct. 1, 2026

(54) SYSTEMS, METHODS, AND COMPUTER PROGRAM PRODUCTS FOR SUBSTRATE PROCESSING

(71) Applicant: ASM IP Holding B.V., Almere (NL)

(72) Inventors: Amir Kajbafvala, Chandler, AZ (US); Jeffrey Robinson, Chandler, AZ (US); Praveen Kumar Gupta, Tempe, AZ (US); Nitin Choudhary, Mesa, AZ (US); Gui He, Avondale, AZ (US); Nisarg Trivedi, Tempe, AZ (US); Zack Zadecki, Peoria, AZ (US); Pradeep Nambiath, Mesa, AZ (US); Caleb Miskin, Mesa, AZ (US); Alexandros Demos, Scottsdale, AZ (US); Hichem M'Saad, Paradise Valley, AZ (US)

(21) Appl. No.: 19/629,356

(22) Filed: Mar. 26, 2026

Related U.S. Application Data
(60) Provisional application No. 63/780,586, filed on Mar. 31, 2025.

(51) Int. Cl. C30B 25/08; C30B 25/10; C30B 25/12; C30B 25/16

(52) U.S. Cl. CPC C30B 25/08; C30B 25/105; C30B 25/12; C30B 25/16

(57) ABSTRACT

A semiconductor processing system includes a chamber body, a gate valve abutting the chamber body, and a controller. The controller operably connected to the gate valve and responsive to instructions recorded on a memory to open the gate valve to load a substrate into the chamber body, close the gate valve to deposit a material layer onto the loaded substrate, and open the gate valve to unload the substrate with the material layer deposited thereon. One or more load operation to load the substrate into the chamber body is executed prior to loading the substrate into the chamber body, and one or more unload operation to unload the substrate with the material layer deposited thereon is executed prior to unloading the substrate from the chamber body. Methods of loading and unloading a substrate into and out of the chamber body and computer program products are also described.

### CROSS-REFERENCE TO RELATED APPLICATIONS

This application claims priority to U.S. Provisional Patent Application Ser. No. 63/780,586 filed Mar. 31, 2025 titled SYSTEMS, METHODS, AND COMPUTER PROGRAM PRODUCTS FOR SUBSTRATE PROCESSING, the disclosure of which is hereby incorporated by reference in its entirety.

### FIELD OF INVENTION

The present disclosure generally relates to processing substrates. More particularly, the present disclosure relates to loading and unloading substrates into a chamber body, such as for the fabrication of semiconductor devices.

### BACKGROUND OF THE DISCLOSURE

Material layers are commonly deposited onto substrates during the fabrication of semiconductor devices, such as integrated circuits and power electronics. Prior to the material layers being deposited onto the substrates, the substrates may be loaded into a chamber body of a semiconductor processing system suitable for depositing a material layer. The loading process may have additional operations prior to the substrate being loaded into a chamber body. Once the substrate is loaded into the chamber body deposition of a material layer onto a substrate may occur. Upon deposition of the material layer onto the substrate, the substrate with the material layers deposited thereon may be unloaded from the chamber body. The unloading process may have additional operations prior to the substrate with material layer deposited thereon from being unloaded from the chamber body. In such deposition processes the load operations and unload operations may not take place simultaneously. While generally satisfactory for its intended purposes, not having some or all of the load operations, followed by the unload operations take place simultaneously may limit the throughput of the semiconductor processing system.

Such methods and systems have generally been considered suitable for their intended purpose. However, there remains a need in the art for improved semiconductor processing systems, substrate processing methods, and related computer program products. The present disclosure provides a solution to this need.

### SUMMARY OF THE DISCLOSURE

A semiconductor processing system is provided. The semiconductor processing system includes a chamber body, a gate valve, and a controller. The gate valve is abutting the chamber body. The controller is operably connected to the gate valve and is responsive to instructions recorded on a non-transitory machine-readable medium to open the gate valve to load a substrate into the chamber body, to close the gate valve to deposit a material layer on to the loaded substrate, and to open the gate valve to unload the substrate with a material layer deposited onto the substrate. The controller further instructs one or more load operation to be executed prior to the loading of the substrate into the chamber body. Additionally, the controller further instructs one or more unload operation to be executed prior to the unloading of the substrate with a material layer deposited thereon from the chamber body.

In addition to one or more of the features described above, or as an alternative, further examples may include a substrate support arranged within the chamber body and plurality of lift pins slidably received within the substrate support which are operably associated with the controller. The plurality of lift pins are movable between a first position and a second position. When in the first position the plurality of lift pins dangle below the substrate support, and when in the second position the plurality of lift pins protrude above the substrate support. Instructions recorded on the memory further cause the controller to move the plurality of lift pins between the first position and the second position prior to opening the gate valve to load the substrate into the chamber body.

In addition to one or more of the features described above, or as an alternative, further examples may include simultaneously with the moving of the plurality of lift pins between the first position and the second position, instructions further causing the controller to flow an etchant into the chamber body and etch an interior of the chamber body using the etchant prior to the load of the substrate into the chamber body.

In addition to one or more of the features described above, or as an alternative, further examples may include simultaneously with the moving of the plurality of lift pins between the first position and the second position, instructions further causing the controller to flow a material layer precursor into the chamber body and form a precoating onto the substrate support arranged within the chamber body prior to the load of the substrate into the chamber body.

In addition to one or more of the features described above, or as an alternative, further examples may include an array of heating elements supported outside the chamber body and operably associated with the controller. The instructions further cause the controller to heat the substrate using a predetermined fixed power value during the load of the substrate into the chamber body.

In addition to one or more of the features described above, or as an alternative, further examples may include the instructions further causing the controller to throttle pressure within the chamber body from a predetermined deposition pressure value to a predetermined unload pressure value prior to opening the gate valve to unload the substrate with the material layer deposited thereon.

In addition to one or more of the features described above, or as an alternative, further examples may include a substrate transfer chamber. The substrate transfer chamber coupled to the chamber body by the gate valve. The predetermined unload pressure value is less than the pressure within the substrate transfer chamber.

In addition to one or more of the features described above, or as an alternative, further examples may include a substrate support arranged within the chamber body upon which the substrate is seated during the deposition of the material layer thereon. Simultaneously with the throttling of the pressure within the chamber body ceasing rotation of the substrate support.

In addition to one or more of the features described above, or as an alternative, further examples may include a substrate support arranged within the chamber body and upon which the substrate is seated during the deposition of the material layer thereon. Simultaneously with the throttling of the pressure within the chamber body, jogging the rotational position of the substrate support to a lift pin actuation rotational position.

In addition to one or more of the features described above, or as an alternative, further examples may include a substrate support arranged within the chamber and a plurality of lift pins slidably received within the substrate support. The plurality of lift pins moveable between a first position, a second position, a third position, and operably associated with the controller. In the first position the plurality of lift pins dangle below the substrate support. In the second position the plurality of lift pins protrude above the substrate support. The third position is separated from the first position by the second position. The instructions recorded on the memory further cause the controller to move the plurality of lift pins between the first position and the third position simultaneously with the throttling of the pressure within the chamber body from the predetermined deposition pressure value to the predetermined unload pressure value.

A method of processing a substrate is provided. A semiconductor processing system including a chamber body, a gate valve abutting the chamber body, and a controller operably connected to the gate valve. The method may include opening the gate valve to load a substrate into the chamber body, closing the gate valve to deposit a material layer onto the loaded substrate, and opening the gate valve to unload the substrate with the material layer deposited thereon.

In addition to one or more of the features described above, or as an alternative, further examples of the method may include a substrate support arranged within the chamber body and a plurality of lift pins slidably received within the substrate support. The plurality of lift pins movable between a first position and a second position. In the first position the plurality of lift pins dangle below the substrate support, and in the second position the plurality of lift pins protrude above the substrate support. The method may include moving the plurality of lift pins between the first position and the second position prior to opening the gate valve to load the substrate into the chamber body.

In addition to one or more of the features described above, or as an alternative, further examples of the method may include flowing an etchant into the chamber body simultaneously with the moving of the plurality of lift pins between the first position and the second position. The etchant etching an interior of the chamber body prior to loading of the substrate into the chamber body. The method may include flowing a material layer precursor into the chamber body simultaneously with the moving of the plurality of lift pins between the first position and the second position. The material layer precursor forming a precoating onto the substrate support prior to the loading of the substrate into the chamber body.

In addition to one or more of the features described above, or as an alternative, further examples of the method may include an array of heating elements supported outside the chamber body. The method may include heating the substrate using a predetermined fixed power value during the loading of the substrate into the chamber body.

In addition to one or more of the features described above, or as an alternative, further examples of the method may include throttling pressure within the chamber body from a predetermined deposition pressure value to a predetermined unload pressure value prior to the opening of the gate valve to unload the substrate with the material layer deposited thereon.

In addition to one or more of the features described above, or as an alternative, further examples of the method may include a substrate support arranged within the chamber body. The method may include ceasing rotation of the substrate support and upon which the substrate is seated during the deposition of the material layer thereon.

In addition to one or more of the features described above, or as an alternative, further examples of the method may include a substrate support arranged within the chamber body. The method may include jogging the rotational position of the substrate support and upon which the substrate is seated during the deposition of the material layer thereon to a lift pin actuation rotational position.

In addition to one or more of the features described above, or as an alternative, further examples of the method may include a substrate arranged within the chamber body and a plurality of lift pins. The plurality of lift pins slidably received within the substrate support and movable between a first position, a second position, and a third position. In the first position the plurality of lift pins dangle below the substrate support. In the second position the plurality of lift pins protrude above the substrate support. The third position is separated from the first position by the second position. The method may include moving the plurality of lift pins to the third position simultaneously with the throttling of the pressure within the chamber body from the predetermined deposition pressure value to the predetermined unload pressure value.

In addition to one or more of the features described above, or as an alternative, further examples of the method may include a substrate support arranged within the chamber body and a plurality of lift pins. The plurality of lift pins slidably received within the substrate support and movable between a first position, a second position, and a third position. In the first position the plurality of lift pins dangle below the substrate support. In the second position the plurality of lift pins protrude above the substrate support. The third position is separated from the first position by the second position. The method may include throttling pressure within the chamber body from a predetermined deposition pressure value to a predetermined unload pressure value prior to opening the gate valve to unload the substrate with the material layer deposited thereon. The method may include ceasing rotation of the substrate support arranged within the chamber body and upon which the substrate is seated during the deposition of the material layer thereon. The method may include jogging the rotational position of the substrate support arranged within the chamber body and upon which the substrate is seated during the deposition of the material layer thereon to a lift pin actuation rotational position. The method may include moving the plurality of lift pins to the third position.

A computer program product is provided. The computer program product includes a non-transitory machine-readable medium having instructions recorded in a plurality of program modules that, when read by a processor operably connected to a chamber arrangement of a semiconductor processing system cause the controller to open a gate valve abutting a chamber body operably associated with the controller to load a substrate into the chamber body, close, using the controller, the gate valve to deposit a material layer onto the substrate, and open, using the controller, the gate valve to unload the substrate with the material layer deposited thereon. Where one or more load operations to load the substrate into the chamber body is executed prior to loading the substrate into the chamber body. Where one or more unload operations to unload the substrate with the material layer deposited thereon is executed prior to unloading the substrate from the chamber body.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic view of a semiconductor processing system in accordance with the present disclosure, showing a plurality of lift pins dangling from a substrate support within a chamber arrangement coupling a precursor source to an exhaust source;

FIG. 2 is a schematic view of the precursor source and a controller of the semiconductor processing system of FIG. 1 according to an example of the present disclosure, showing the precursor source communicating a material layer precursor to the chamber arrangement to form a material layer onto a substrate;

FIG. 3 is a schematic view of the chamber arrangement of FIG. 1 according to an example of the present disclosure, showing the material layer being deposited on the substrate;

FIGS. 4-9 are a schematic view of operations for loading and unloading the substrate into a chamber body of the chamber arrangement of FIG. 1;

FIGS. 10-12 are a block diagram of a method of loading and unloading the substrate into the chamber body, showing operations of the method according to an illustrative and non-limiting example.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

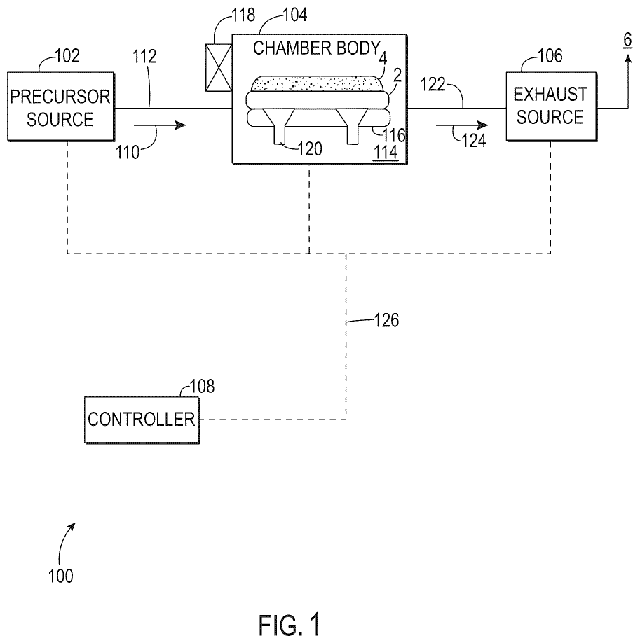

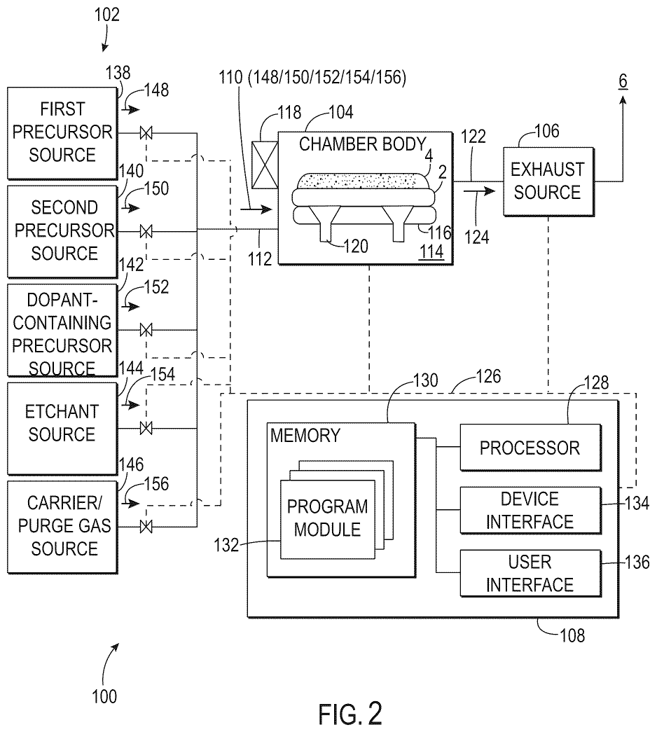

Reference will now be made to the drawings wherein like reference numerals identify similar structural features or aspects of the subject disclosure. For purposes of explanation and illustration, and not limitation, a partial view of a semiconductor processing system in accordance with the present disclosure is shown in FIG. 1 and is designated generally by reference numeral 100. Other examples of semiconductor processing systems with operations for loading and unloading a substrate within a chamber body, methods of loading and unloading the substrate within the chamber body, and related semiconductor operations and computer implemented process for loading and unloading the substrate within the chamber body in accordance with the present disclosure, or aspects thereof, are provided in FIGS. 2-12, as will be described. The systems and methods of the present disclosure may be used for loading and unloading a substrate into and out of the chamber body, such as in semiconductor processing systems employed to deposit semiconductor-containing material layers onto substrates formed from semiconductor materials using epitaxial deposition techniques during the fabrication of semiconductor devices, though the present disclosure is not limited to any particular deposit technique or to the fabrication of semiconductor devices in general.

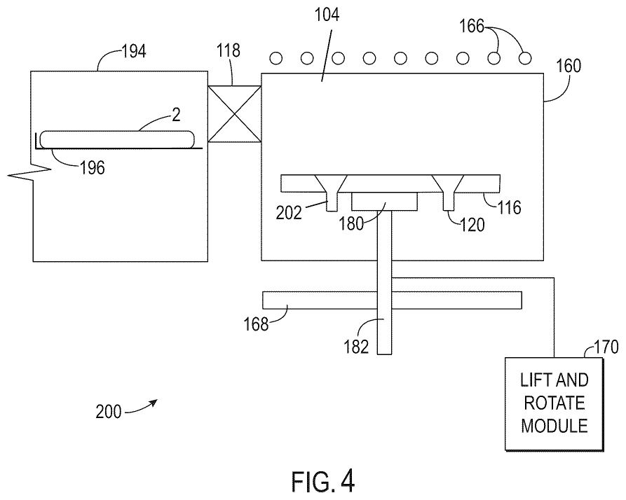

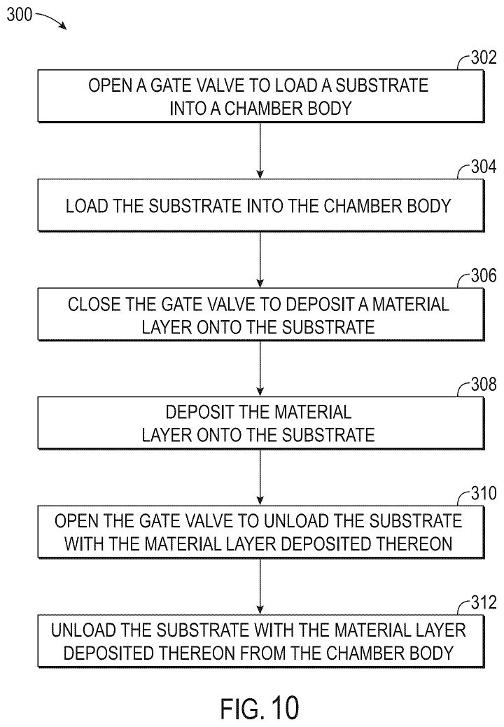

Referring to FIG. 1, the semiconductor processing system 100 is shown. The semiconductor processing system 100 includes a precursor source 102, a chamber arrangement 104, an exhaust source 106, and a controller 108. The precursor source 102 is configured to communicate a material layer precursor 110 to the chamber arrangement 104 and in this respect is coupled to the chamber arrangement 104 by a precursor supply conduit 112. The chamber arrangement 104 is configured to support a substrate 2 during the deposition of a material layer 4 on the substrate 2 using the material layer precursor 110. The substrate 2 is supported within a hollow interior 114 of the chamber arrangement 104 by a substrate support 116. The substrate 2 may be loaded and unloaded from the chamber arrangement 104 by a robotic arm with end-effector 196 (shown in FIGS. 4-9) through a gate valve 118 abutting the chamber arrangement 104. The substrate 2 may be seated onto and unseated from the substrate support 116 by a plurality of lift pins 120 slidably received by the substrate support 116. The material layer precursor 110 flows into the chamber arrangement 104, and the chamber arrangement 104 is coupled to the exhaust source 106 by an exhaust conduit 122. The exhaust source 106 is configured to communicate a flow of residual material layer precursor and/or reaction products 124 to an external environment 6, and may include one or more vacuum pump and an abatement device such as a scrubber and/or burn box. The controller 108 includes a processor 128 (shown in FIG. 2) operably associated with one or more elements of the semiconductor processing system 100, e.g., the precursor source 102 and/or the chamber arrangement 104 through a wired or wireless link 126, and is configured to cause the loading and unloading of the substrate 2 into and out of the chamber arrangement 104 through the wired or wireless link 126 according to instructions contained in a plurality of program modules 132 (shown in FIG. 2) recorded on a non-transitory machine readable medium of memory 130 (shown in FIG. 2) that the causes the processor 128 to execute operations of the method 300 (shown in FIGS. 10-12) of loading and unloading the substrate 2, as will be described.

As used herein the term “substrate” may refer to any underlying material or materials, including any underlying material or materials that may be modified, or upon which, a device, a circuit, or a film may be formed. A substrate may be continuous or non-continuous; rigid or flexible; solid or porous; and combinations thereof. A substrate may be in any form such as (but not limited to) a powder, a plate, or a workpiece. A substrate in the form of a plate may include a wafer in various shapes and sizes, for example, including 300-millimeter wafers. A substrate may be formed from semiconductor materials, including, for example, silicon (Si), silicon-germanium (SiGe), silicon oxide (SiO₂), gallium arsenide (GaAs), gallium nitride (GaN) and silicon carbide (SiC). A substrate may include a pattern or may be unpatterned, such as a so-called blanket-type substrate. As examples, substrates in the form of a powder may have applications for pharmaceutical manufacturing. A porous substrate may include one or more polymers. Examples of workpieces may include medical devices (for example, stents and syringes), jewelry, tooling devices, components for battery manufacturing (for example, anodes, cathodes, or separators) or components of photovoltaic cells, etc. A continuous substrate may extend beyond the bounds of a process chamber where a deposition process occurs. In some processes, a continuous substrate may move through the process chamber such that the process continues until the end of the substrate is reached. A continuous substrate may be supplied from a continuous substrate feeding system to allow for manufacture and output of the continuous substrate in any appropriate form. Non-limiting examples of continuous substrates may include sheets, non-woven films, rolls, foils, webs, flexible materials, bundles of continuous filaments or fibers (for example, ceramic fibers or polymer fibers). A continuous substrate may also comprise a carrier or sheet upon which one or more non-continuous substrate is mounted.

With reference to FIG. 2, the precursor source 102 and the controller 108 of the semiconductor processing system 100 are shown according to an example of the present disclosure. In this illustrated example the precursor source 102 includes a first precursor source 138, a second precursor source 140, and a dopant-containing precursor source 142. In the illustrated example the precursor source also includes an etchant source 144 and a carrier or purge gas source 146. Although shown and described herein as having a specific arrangement, it is to be understood and appreciated that the precursor source 102 may have different arrangement in other examples and remain within the scope of the present disclosure.

The first precursor source 138 may be configured to communicate a first precursor 148 to the chamber arrangement 104. In this respect it is contemplated that the first precursor source 138 include the first precursor 148 and be coupled to the chamber arrangement 104 by the precursor supply conduit 112. In further respect, it is also contemplated that the first precursor source 138 may be coupled to the chamber arrangement 104 by a flow control device, such as through a metering valve and/or a mass flow controller (MFC) device, which may in turn itself be operably associated with the controller 108. In certain examples the first precursor 148 may include one or more silicon-containing precursor. Examples of suitable silicon-containing precursors include non-chlorinated silicon-containing precursors such as silane (SiH₄), disilane (Si₂H₆), and trisilane (Si₃H₈). Examples of suitable chlorinated silicon-containing precursors include dichlorosilane (SiH₂Cl₂), trichlorosilane (SiHCl₃), and silicon tetrachloride (SiCl₄).

The second precursor source 140 may be similar to the first precursor source 138 and is additionally configured to communicate one or more second precursor 150 to the chamber arrangement 104. In this respect the second precursor source 140 may by coupled to the chamber arrangement 104 by the precursor supply conduit 112. In further respect the second precursor source 140 may be coupled to the chamber arrangement 104 by a flow control device such as second precursor metering valve and/or a second precursor MFC device operably associated with the controller 108. In certain examples the second precursor 150 may include a metal, such as germanium (Ge), gallium (Ga), or aluminum (Al). Examples of suitable germanium-containing precursors include germane (GeH₄), germanium tetrachloride (GeCl₄), and digermane (Ge₂H₆). Other material layer precursors may include organometallic precursors and halides. In some embodiments, a material layer precursor may comprise one or more elements selected from hydrogen, an alkaline metal, an alkaline earth metal, a transition metal, a lanthanide, a post transition metal, a group 13 element, a group 14 element, a chalcogen, a pnictogen, a halogen, and a noble gas.

The dopant-containing precursor source 142 may be configured to communicate one or more dopant-containing precursor 152 to the chamber arrangement 104 and in this respect may be coupled to the chamber arrangement 104 by the precursor supply conduit 112. In certain examples the dopant-containing precursor 152 may include a p-type dopant. Examples of suitable p-type dopants include boron (B), and in this respect the dopant-containing precursor 152 may include a boron-containing precursor such as diborane (B₂H₆). In accordance with certain examples, the dopant-containing precursor 152 may include an n-type dopant, such as arsenic (As) or phosphorous (P), the dopant-containing precursor source 142 including arsine (AsH₃) and/or phosphine (PH₃) in such examples.

The etchant source 144 may be configured to communicate an etchant 154 to the chamber arrangement 104, for example through the precursor supply conduit 112 and/or through a separated supply conduit. In certain examples the etchant source 144 may be coupled to the chamber arrangement 104 through a flow control device, such as an etchant metering valve and/or an etchant supply MFC device operably associated with the controller 108 and include the etchant 154. In accordance with certain examples, the etchant may be co-flowed to the chamber arrangement 104 with one or more of the first precursor 148, the second precursor 150, and/or the dopant-containing precursor 152, for example to provide selectivity of deposition of the material layer 4 on the substrate 2. Non-limiting examples of suitable etchants include halide-containing etchants, such as chlorine-containing etchants like hydrochloric (HCl) acid and chlorine (Cl₂) gas and fluorine-containing etchants like hydrogen fluoride (HF) and fluorine (F₂) gas.

The carrier or purge gas source 146 may be configured to communicate a carrier or purge gas 156 to the chamber arrangement 104, for example independent of one or more of the aforementioned precursors and etchants (e.g., as a purge gas) as well as intermixed with one or more of the aforementioned precursors and etchants through the precursor supply conduit 112. In this respect the carrier or purge gas 156 may be employed as a diluent and/or carrier of one or more of the precursors and/or etchants communicated to the chamber arrangement 104. Non-limiting examples of carrier or purge gases include hydrogen (H₂) gas as well as inert gases like as nitrogen (N₂) gas, argon (Ar) gas, helium (He) gas, krypton (Kr) gas as well as mixtures including one of the aforementioned gases. In the illustrate example the material layer precursor 110 may be selected from one or more of the first precursor 148, the second precursor 150, the dopant-containing precursor 152, the etchant 154, or the carrier or purge gas 156 and flowed individually or in combination and remaining within the scope of the present disclosure.

In the illustrated example the controller 108 includes a device interface 134, the processor 128, a user interface 136, and the memory 130. The device interface 134 couples the processor 128 to one or more of the precursor source 102, the chamber arrangement 104, and/or the exhaust source 106. The processor 128 is disposed in communication with the user interface 136, for example to receive a user input and/or provide a user output therethrough, and the memory 130. The memory 130 includes a non-transitory machine-readable medium having the plurality of program modules 132 recorded thereon. It is contemplated that the plurality of program modules 132 contain instructions that, when read by the processor 128, cause the processor 128 to execute certain operations, and in this respect may be included in the plurality of program modules 132. Among the operations are the operations of the method 300 (shown in FIG. 10), as will be described. Although shown and described herein as having a specific architecture it is to be understood and appreciated that the controller 108 may have different architectures in other examples, for example a distributed computing architecture, and remain within the scope of the present disclosure.

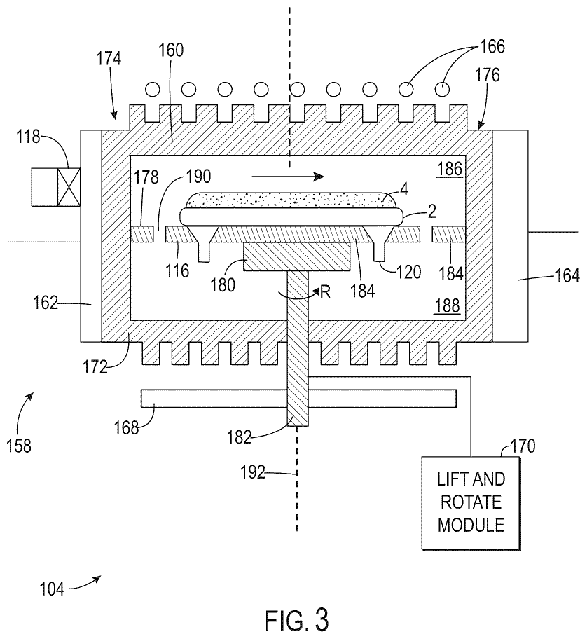

With reference to FIG. 3, the chamber arrangement 104 is shown according to an example of the present disclosure. In the illustrated example the chamber arrangement 104 is a gas-phase chamber arrangement having a single-wafer crossflow architecture 158 and includes a chamber body 160, an injection flange 162, an exhaust flange 164, and the gate valve 118. In the illustrated example the chamber arrangement 104 also includes an upper heater element array 166, a lower heater element array 168, and a lift and rotate module 170. It is contemplated that the lift and rotate module 170 may be operably associated with the controller 108, for example through a wired or wireless link 126, to seat the substrate 2 on the substrate support 116 prior to the deposition of the material layer 4 onto the substrate 2 and unseat the substrate 2 from the substrate support 116 subsequent to deposition of the material layer 4 onto the substrate 2. It is contemplated that seating and unseating of the substrate 2 be in cooperation with the gate valve 118 and the movement of the plurality of lift pins 120. Although shown and described herein as having a specific arrangement and including certain elements, it is to be understood and appreciated that the chamber arrangement 104 may have a different arrangement in other examples (e.g., a multi-wafer arrangement), and/or include additional elements as well as exclude elements shown and described herein, and remain within the scope of the disclosure.

The chamber body 160 is formed from a transparent material 172, which bounds the hollow interior 114 of the chamber body 160, and which further extends between an injection end 174 and a longitudinally opposite exhaust end 176. The exhaust flange 164 abuts the exhaust end 176 of the chamber body 160, is coupled to the exhaust source 106 (shown in FIG. 1) by the exhaust conduit 122, and fluidly couples the hollow interior 114 of the chamber body 160 to the exhaust source 106. The injection flange 162 abuts the injection end 174 of the chamber body 160, is coupled to the precursor source 102 (shown in FIG. 1) by the precursor supply conduit 112, and fluidly couples the precursor source 102 to the hollow interior 114 of the chamber body 160. In accordance with certain examples, the chamber body 160 may include a plurality of external ribs extending laterally about exterior surfaces of the chamber body 160 and laterally spaced apart from one another between the injection end 174 and the exhaust end 176 of the chamber body 160. It is contemplated that the chamber body 160 may not include the plurality of external ribs and remaining within the scope of the present disclosure.

It is contemplated that the upper heater element array 166 may include a plurality of heater elements, for example linear or bulb-type filament lamps, and is configured to heat the substrate 2 using radiant energy (e.g., electromagnetic radiation within an infrared waveband) communicated into the hollow interior 114 of the chamber body 160 through the transparent material 172 forming the chamber body 160. The lower heater element array 168 may be similar to the upper heater element array 166 and is additionally supported below the chamber body 160. The lower heater element array 168 may further be configured to heat the substrate 2 using radiant energy communicated into the hollow interior 114 of the chamber body 160 through the transparent material 172 forming the chamber body 160. In certain examples the transparent material 172 may include (or consist of or consist essentially of) a ceramic material, such as quartz or sapphire by way of non-limiting example.

It is contemplated that the chamber arrangement 104 include a divider 178, the substrate support 116, a support member 180, and a shaft member 182. The divider 178 may be formed from an opaque material 184 (e.g., a material opaque to electromagnetic radiation within an infrared waveband such as silicon carbide or a carbonaceous material like graphite or pyrolytic carbon with a silicon carbide coating), is seated within the hollow interior 114 of the chamber body 160, and divides the hollow interior 114 of the chamber body 160 into an upper chamber 186 and a lower chamber 188. The divider 178 may further define a divider aperture 190 therethrough, the divider aperture 190 in turn fluidly coupling the lower chamber 188 of the chamber body 160 to the upper chamber 186 of the chamber body 160. It is further contemplated that the substrate support 116 may be supported (at least in part) within the divider aperture 190 for rotation about a rotation axis 192, that the substrate support 116 may be formed from the opaque material 184, and that the substrate support 116 be configured to support the substrate 2 during the forming of the material layer 4 on the substrate 2.

The support member 180 may be arranged within the lower chamber 188 of the chamber body 160 and along the rotation axis 192, may be fixed in rotation R relative to the substrate support 116 about the rotation axis 192, and couple the substrate support 116 to the shaft member 182. In this respect the substrate support 116 is operably associated with the lift and rotate module 170. It is contemplated that the shaft member 182 in turn may be fixed in rotation R about the rotation axis 192 relative to the support member 180, be arranged along the rotation axis 192 and extend through a lower wall of the chamber body 160, and operably couple the lift and rotate module 170 to the substrate support 116 through the support member 180. The lift and rotate module 170 may be configured to rotate the substrate support 116 about the rotation axis 192 through the shaft member 182 and the support member 180 as well as seat and unseat substrates (e.g., the substrate 2) from the substrate support 116, for example using the plurality of lift pins 120 slidably received by the substrate support 116. It is contemplated that the shaft member 182 and plurality of lift pins 120 may be operably associated with the lift and rotate module 170. In certain examples either (or both) the support member 180 and the shaft member 182 may be formed from transparent material, such as the transparent material 172.

With reference to FIGS. 4-9, the operations of loading the substrate 2 into the chamber body 160 and unloading the substrate 2 from the chamber body 160 are showing according to illustrative examples which are not intended to limit the present disclosure. In certain examples, the plurality of lift pins 120 may move between one or more positions 200. As shown in FIG. 4, the chamber arrangement 104 further includes a substrate transfer chamber 194 and the robotic arm with end-effector 196. The substrate transfer chamber 194 may interface with additional chamber bodies and/or substrate cassettes for additional processing of the substrates (e.g., the substrate 2) and may include additional substrate robotic arms with end-effectors (e.g., the robotic arm with end-effector 196). The substrate transfer chamber 194 abuts the gate valve 118 and is fluidly coupled to the chamber body 160 through the gate valve 118. As shown in FIG. 4, the substrate 2 is positioned outside the chamber body 160 and is being held by the robotic arm with end-effector 196 within the substrate transfer chamber 194. The gate valve 118 is currently in the closed position, and the plurality of lift pins 120 are in a first position 202. In the first position 202 the plurality of lift pins 120 dangle below the substrate support 116.

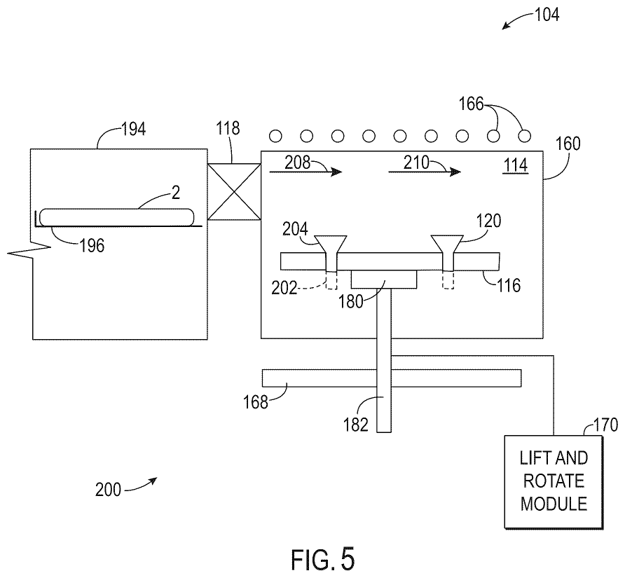

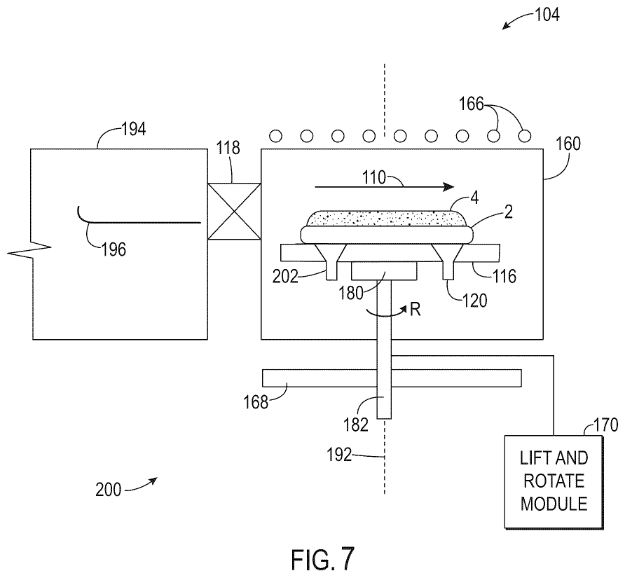

As shown in FIG. 5, an etchant 210 and/or a material layer precursor 208 are flowed into the chamber body 160 simultaneously with the movement of the plurality of lift pins 120 between the first position 202 and a second position 204. The controller 108 may cause the plurality of lift pins 120 to move between the first position 202 and the second position 204 in preparation to seat the substrate 2 on the plurality of lift pins 120. In the second position 204 the plurality of lift pins 120 protrude above the substrate support 116. Instructions recorded on the plurality of program modules 132 may cause the etchant 210 and/or the material layer precursor 208 to be flowed into the hollow interior 114 of the chamber body 160. Flowing the etchant 210 into the interior of the chamber body may result in an etch of the hollow interior 114 of the chamber body 160. The etchant may etch and caused to be removed residual material layer precursor 124 that was not previously removed. Removing residual material layer precursor 124 may prevent shadowing effects onto the substrate 2 from the upper heater element array 166. Additionally, flowing the etchant 210 into the hollow interior 114 of the chamber body 160 may also remove residual material layer precursor 124 from the plurality of lift pins 120 to prevent binding with the substrate support 116 as the plurality of lift pins 120 move between the first position 202 and the second position 204. Flowing the material layer precursor 208 into the chamber body may form a precoating on the substrate support 116 such that when the substrate 2 is seated on the substrate support 116 (shown in FIG. 7) the backside of the substrate 2 does not experience any deleterious effects. As will be appreciated by those skilled in the art in view of the present disclosure, performing the operations of moving the plurality of lift pins 120 between the first position 202 and the second position 204 while simultaneously flowing the etchant 210 and the material layer precursor 208 into the chamber body 160 may increase the throughput of the chamber arrangement 104.

It is contemplated that flowing the etchant 210 into the hollow interior 114 of the chamber body 160 may occur simultaneously with the movement of the plurality of lift pins 120 between the first position 202 and the second position 204. This may be followed by the flow of the material layer precursor 208 into the chamber body 160 to form a precoating onto the substrate support 116. Alternatively, it is further contemplated that the flow of the material layer precursor 208 into the chamber body 160 may occur simultaneously with the movement of the plurality of lift pins 120 between the first position 202 and the second position 204. This may be followed by the flow of the etchant 210 into the hollow interior 114 of the chamber body 160. In both of these alternatives as will be appreciated by those skilled in the art in view of the present disclosure that performing two of the operations simultaneously with one another may increase the throughput of the chamber arrangement 104.

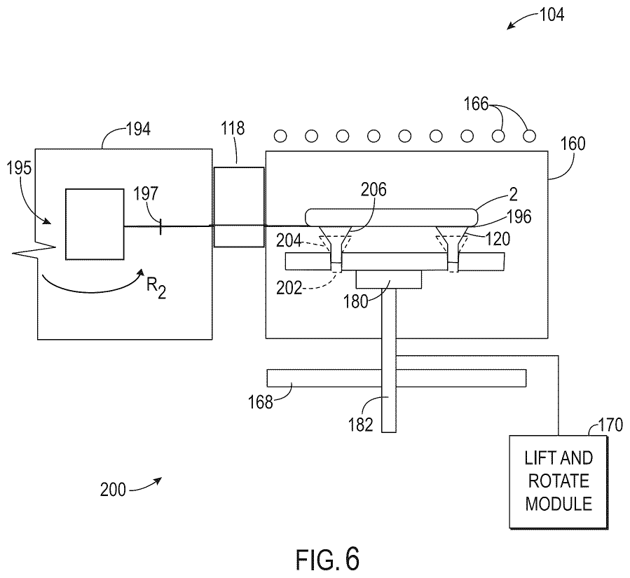

As shown in FIG. 6, prior to opening the gate valve 118 and loading the substrate 2 into the chamber body 160, the instructions recorded on the plurality of program modules 132 (shown in FIG. 2) may cause the upper heater element array 166 and the lower heater element array 168 to heat the chamber body 160 using a predetermined fixed power value. The instructions recorded on the plurality of program modules 132 (shown in FIG. 2) have caused the gate valve 118 to change its state from a closed position (as shown in FIG. 5) to an open position and the robotic arm with end-effector 196 to introduce the substrate 2 into the chamber body 160 such that the substrate 2 may seated on the plurality of lift pins 120. The plurality of lift pins 120 may move between the second position 204 and a third position 206 such that the substrate 2 may be seated on the plurality of lift pins 120 and the robotic arm with end-effector 196 may retract and return to the substrate transfer chamber 194. The third position 206 differs from the second position 204 and the first position 202, with the second position 204 between the first position 202 and the third position 206. As the robotic arm with end-effector 196 introduces the substrate 2 into the chamber body 160, the instructions recorded on the plurality of program modules 132 (shown in FIG. 2) may cause the upper heater element array 166 and the lower heater element array 168 to heat the substrate 2 using the predetermined fixed power value. As will be appreciated by those in the art in view of the present disclosure, the substrate transfer chamber 194 and chamber body 160 may operate under different thermal environments. As the gate valve 118 opens the thermal difference between the substrate transfer chamber 194 and chamber body 160 may reduce (e.g., the substrate transfer chamber 194 and the chamber body 160 may try to achieve thermal equilibrium upon opening of the gate valve 118). It is contemplated that the chamber body 160 may operate at a higher temperature than the substrate transfer chamber 194. Applying the predetermined fixed power value to the upper heater element array 166 and the lower heater element array 168 may reduce the time required to restore the temperature of the chamber body 160 to near material deposition temperature. Additionally, by heating the chamber body 160 and the substrate 2 during this operation the upper heater element array 166 and the lower heater element array 168 may also heat the substrate 2 to a temperature required for proper adhesion of the material layer precursor 110 onto the substrate 2. As will be appreciated by those skilled in the art in view of the present disclosure, applying the predetermined fixed power value during this operation may increase the throughput of the chamber arrangement 104 by reducing the time required to bring the chamber arrangement 104 back to a temperature for material layer deposition while simultaneously bringing the substrate 2 up to the desired temperature for depositing the material layer 4 thereon.

In an alternative example, the substrate transfer chamber 194 may include a rotational tower 195 coupled to one or more robotic arm with end-effector by a mechanical means (e.g., the coupling mechanism 197 coupling the robotic arm with end-effector 196 and a second robotic arm with end-effector coupled by a mechanical means (not shown) to the rotational tower 195). The rotational tower 195 may be responsive to instructions recorded on the plurality of program modules 132 that may cause the rotational tower 195 to rotate R₂ simultaneously as the gate valve 118 is opened. The rotational tower 195 may further interact with one or more additional chamber body for alternative and/or additional material layer deposition (not shown). As will be appreciated by those skilled in the art in view of the present disclosure, having one or more robotic arm with end-effector within the substrate transfer chamber 194 may increase the throughput of the chamber arrangement 104.

As shown in FIG. 7, instructions recorded on the plurality of program modules 132 may cause the robotic arm with end-effector 196 to retract from the chamber body 160 and return to the substrate transfer chamber 194 once the substrate 2 has been seated on the plurality of lift pins 120 while the plurality of lift pins 120 may be in the third position 206. The controller may cause the gate valve 118 to close following the return of the robotic arm with end-effector 196 to the substrate transfer chamber 194. The controller 108 may cause the plurality of lift pins 120 to move between the third position 206 and the first position 202 so that the substrate 2 may now be seated on the substrate support 116. Additionally, the lift and rotate module 170 may cause the shaft member 182, the support member 180, substrate support 116, and substrate 2 to rotate about the rotation axis 192 at a fixed rotation R. As the substrate 2 rotates about rotation axis 192 the material layer precursor 110 is flowed into the chamber body from the precursor source 102 (shown in FIG. 1) and material layer 4 is deposited onto the substrate 2. Referring back to FIG. 2, the material layer precursor 110 may be selected from one or more of the first precursor 148, the second precursor 150, the dopant-containing precursor 152, the etchant 154, or the carrier or purge gas 156.

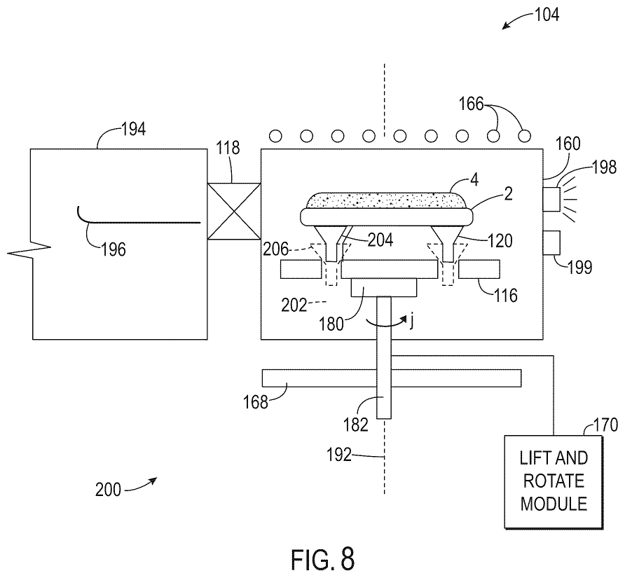

As shown in FIG. 8, the chamber body 160 may include a pressure release conduit 198 and a pressure increase conduit 199. The pressure release conduit 198 and the pressure increase conduit 199 are fluidly coupled to the hollow interior 114 of the chamber body 160 through a wall of the chamber body 160. Prior to opening the gate valve 118 and unloading the substrate 2 with a material layer 4 deposited thereon from the chamber body 160, instructions recorded on the plurality of program modules 132 may cause the chamber arrangement 104 to adjust the pressure of the chamber body 160. It is contemplated that the pressure within the chamber body 160 may be adjusted from a predetermined deposition pressure value to a predetermined unload pressure value prior to opening the gate valve 118. Adjustment of the pressure may be accomplished by releasing pressure from within the chamber body 160 through the pressure release conduit 198 and onward to an external environment 6. For example, the pressure within the chamber body 160 may be adjusted so that the pressure within the chamber body 160 is less than 1 Torr lower than the pressure of the substrate transfer chamber 194. In other examples, the pressure within the chamber body 160 may be adjusted so that the pressure within the chamber body 160 may be lower than the substrate transfer chamber 194 by more than 1 Torr but less than 10 Torr. In other examples the pressure within the chamber body 160 may be adjusted such that the pressure within the chamber body 160 is lower than the pressure in the substrate transfer chamber by more than 10 Torr and remain within the scope of the present disclosure. Alternatively, it is contemplated that if pressure within the chamber body 160 is to be increased pressure may be increased through the pressure increase conduit 199 by pulling vacuum through the pressure increase conduit. As will be appreciated by those skilled in the art in view of the present disclosure, adjusting the pressure of the chamber body 160 may prevent flow of residual material layer precursor and/or reaction products 124 from entering into the substrate transfer chamber 194.

It is also contemplated that the lift and rotate module 170 may cause the substrate support 116 to cease rotation (R) within the chamber body 160 and may cause the shaft member 182 to jog J about the rotation axis 192 to orientate the plurality of lift pins 120 to unseat the substrate 2 from the substrate support 116. As will be appreciated by those skilled in the art in view of the present disclosure, following the rotation R of the substrate 2, substrate support 116, support member 180, and shaft member 182 during the deposition of the material layer 4 onto the substrate 2, the plurality of lift pins 120 may not be properly orientated for the actuation of the movement of the plurality of lift pins 120 by the controller 108. Jogging J of the substrate support 116 may orientate the plurality of lift pins 120 into a lift pin actuation rotational position. As will be appreciated by those skilled in the art in view of the present disclosure, adjusting the pressure of the chamber body 160 while simultaneously ceasing the rotation of the substrate support 116 and jogging J the rotational position of the substrate support 116 may increase the throughput of the chamber arrangement 104.

It is also contemplated that the controller 108 may cause the plurality of lift pins 120 to move between the first position 202 and the third position 206 simultaneously with the throttling of the pressure within the chamber body 160. Moving the plurality of lift pins 120 between the first position 202 and the third position 206 may unseat the substrate 2 with material layer 4 thereon from the substrate support 116. Additionally, moving the plurality of lift pins 120 between the first position 202 and the third position 206 prepares for the robotic arm with end-effector 196 to remove the substrate 2 with material layer 4 thereon from the chamber body 160 through the gate valve 118 and may proceed for additional processing. As will be appreciated by those skilled in the art in view of the present disclosure, the simultaneous movement of the plurality of lift pins 120 between the first position 202 and the third position 206 with the pressure adjustment may increase the throughput of the chamber arrangement 104 by placing the substrate 2 with material layer 4 deposited thereon in a position to be unloaded from the chamber body 160 once the chamber body 160 pressure reaches the predetermined unload pressure value.

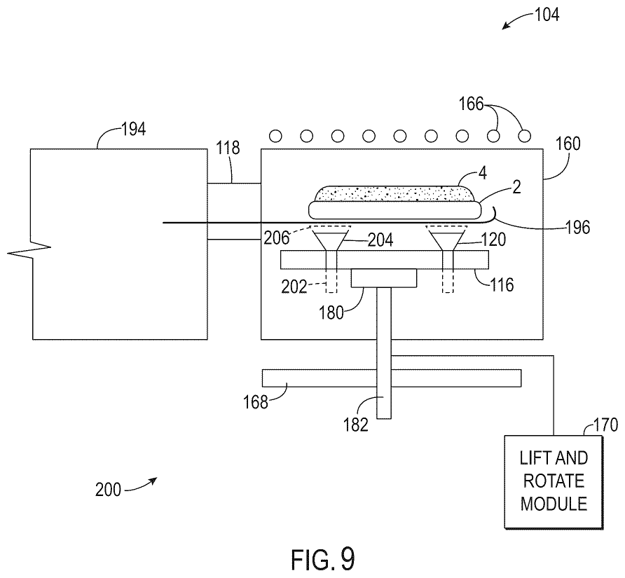

As shown in FIG. 9, instructions recorded on the controller 108 may cause the gate valve 118 to open, and instruct the robotic arm with end-effector 196 to enter the chamber body 160 from the substrate transfer chamber 194. The robotic arm with end-effector 196 may pick the substrate 2 with material layer 4 thereon from the plurality of lift pins 120 and unload the substrate 2 with material layer 4 thereon from the chamber body 160. The controller 108 may cause the plurality of lift pins to return to a position between the first position 202 and the second position 204, prepared to receive a subsequent substrate. As will be appreciated by those skilled in the art in view of the present disclosure, by moving the plurality of lift pins 120 to a position between the first position 202 and the second position 204 may increase throughput as the controller 108 does not need to instruct the plurality of lift pins 120 to return to the first position 202 and then return back to the second position 204.

The throughput of the chamber arrangement 104 may increase by executing one or more load operations prior to loading the substrate 2 into the chamber body 160 and by executing one or more the unload operations prior to unloading the substrate 2 with the material layer 4 deposited thereon. As will be appreciated by those skilled in the art in view of the present disclosure, executing one or more load operations may include moving the plurality of lift pins 120 between the first position 202 and the second position 204 while simultaneously flowing the etchant 210 and/or the material layer precursor 208 into the chamber body 160 which may increase the throughput of the chamber arrangement 104. Flowing the etchant 210 may clean the chamber body 160 and the plurality of lift pins 120 prior to loading the substrate 2 into the chamber body 160, and the flow of the material layer precursor 208 may provide a suitable interface for the backside of the substrate 2 when seated on the substrate support 116. Additionally, one or more load operations may include applying the predetermined fixed power value to the upper heater element array 166 and the lower heater element array 168. Applying the predetermined fixed power value to the upper heater element array 166 and the lower heater element array may reduce the time required to bring the chamber arrangement 104 back to a temperature for material layer deposition while simultaneously bringing the substrate 2 up to the desired temperature for depositing the material layer 4 thereon.

As will be appreciated by those skilled in the art in view of the present disclosure, executing one or more unload operations may include throttling pressure within the chamber body 160 from the predetermined deposition pressure value to the predetermined unload pressure value. Simultaneously with adjusting the pressure of the chamber body 160, ceasing the rotation of the substrate support 116 and jogging J the rotational position of the substrate support 116 may increase the throughput of the chamber arrangement 104. Jogging J the rotational position of the substrate support 116 may orientate the plurality of lift pins 120 into a lift pin actuation rotational position. Simultaneously with adjusting the pressure of the chamber body 160, the movement of the plurality of lift pins 120 between the first position 202 and the third position 206 may increase the throughput of the chamber arrangement 104 by placing the substrate 2 with material layer 4 deposited thereon in a position to be unloaded from the chamber body 160 once the chamber body 160 pressure reaches the predetermined unload pressure value.

With reference to FIGS. 10-12, the method 300 of loading a substrate and unloading a substrate into a chamber body, e.g., the operations shown in FIGS. 4-9, is shown according to an example of the present disclosure. As shown in FIG. 10, the method 300 includes opening a gate valve to load a substrate into the chamber body, e.g., opening the gate valve 118 to load the substrate 2 using the robotic arm with end-effector 196 into the chamber body 160 (shown in FIG. 6), as shown with box 302. Once the substrate is within the chamber body, the substrate is placed onto a plurality of lift pins and seated onto a substrate support, e.g., the plurality of lift pins 120 moving between the third position 206 and the first position 202 and the substrate 2 seated on the substrate support 116 (shown in FIG. 7), as shown with box 304. The robotic arm with end-effector is retracted from the chamber body and the gate valve is closed, e.g., the robotic arm with end-effector 196 is retracted into the substrate transfer chamber 194 and the gate valve 118 is closed (shown in FIG. 7), as shown with box 306. A material layer precursor may be flowed into the chamber body to deposit a material layer onto the substate, e.g., the material layer precursor 110 may flow into the chamber body 160 and deposit the material layer 4 on the substrate 2 (shown in FIG. 7), as shown with box 308. The substrate with material layer deposited thereon may be unloaded from the chamber body. The gate valve may open to unload the substrate with material layer deposited thereon, e.g., opening the gate valve 118 (shown in FIG. 9), as shown with box 310. The substrate with material layer deposited thereon may be unloaded from the chamber body using the robotic arm with end-effector, e.g., the robotic arm with end-effector 196 to remove the substrate 2 with material layer 4 deposited thereon from the chamber body 160 (shown in FIG. 9), as shown with box 312.

Depositing 308 the material layer onto the substrate may include flowing a material layer precursor into the chamber arrangement e.g., the material layer precursor 110 (shown in FIG. 1). In certain examples the material layer precursor may be a first precursor and may include a silicon-containing precursor, e.g., the first precursor 148 (shown in FIG. 2). In accordance with certain examples, the first precursor may include a chlorinated silicon-containing precursor such as dichlorosilane (SiH₂Cl₂), trichlorosilane (SiHCl₃), and/or silicon tetrachloride (SiCl₄). It is contemplated that the first precursor may (alternatively or additionally) include a non-chlorinated silicon-containing precursor such as silane (SiH₄), disilane (Si₂H₆), and/or trisilane (Si₃H₈).

Depositing 308 may include flowing a second precursor into the chamber arrangement, e.g., the second precursor 150 (shown in FIG. 2). In certain examples the second precursor may include a metal-containing precursor, such as germanium (Ge), aluminum (Al), and/or gallium (Ga). In this respect it is contemplated that the second precursor may include a chlorinated metal-containing precursor, such as germanium tetrachloride (GeCl₄), or a non-chlorinated metal-containing precursor like germane (GeH₄) or digermane (GeH₄). Other material layers precursors may include organometallic precursors and halides. In some embodiments, a material layer precursor may comprise one or more elements selected from hydrogen, an alkaline metal, an alkaline earth metal, a transition metal, a lanthanide, a post transition metal, a group 13 element, a group 14 element, a chalcogen, a pnictogen, a halogen, and a noble gas.

Depositing 304 may include flowing a dopant-containing precursor into the chamber arrangement, e.g., the dopant-containing precursor 152 (shown in FIG. 2). In this respect it is contemplated that the dopant-containing precursor may include a p-type dopant, such as boron (B), such as may be flowed into the chamber arrangement a dopant-containing precursor such as diborane (B₂H₆). It is also contemplated that the dopant-containing precursor may include an n-type dopant like arsenic (As) and/or phosphorous (P), which may be included flowed into the chamber arrangement using arsine (AsH₃) and/or phosphine (PH₃).

Depositing 304 may include flowing an etchant into the interior of the chamber arrangement, e.g., the etchant 154 (shown in FIG. 2). In certain examples the etchant may include chlorine (Cl) and in this respect may include chlorine (Cl₂) gas and/or hydrochloric (HCl) acid. It is contemplated that the dopant-containing precursor and/or the etchant may be co-flowed into the chamber arrangement with one or more of the first precursor, the second precursor, and/or the dopant-containing precursor, for example to provide selectivity of deposition of the material layer onto the substrate.

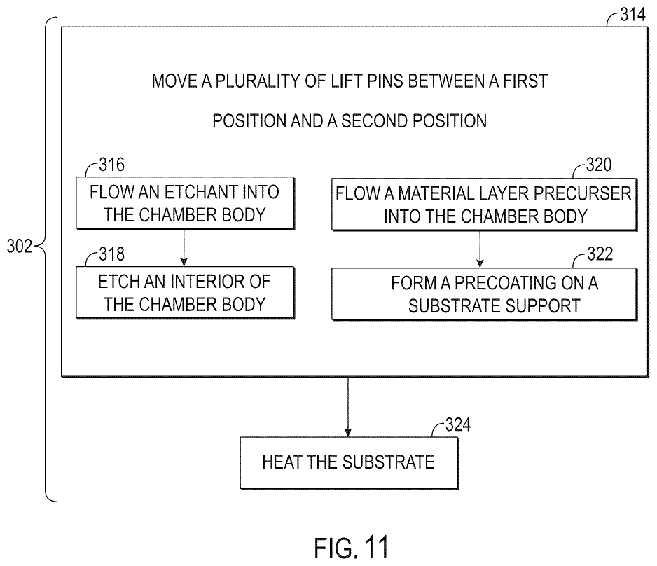

As shown in FIG. 11, opening the gate valve to load 302 the substrate into the chamber body may include one or more load operation being executed prior to loading the substrate into the chamber body, e.g., the operations of FIGS. 5-6, as shown with bracket 302. Opening the gate valve to load 302 the substrate into the chamber body may include moving a plurality of lift pins between a first position and a second position, e.g., the plurality of lift pins 120 moving between the first position 202 and the second position 204 (shown in FIG. 5), as shown with box 314. Opening the gate valve to load 302 the substrate into the chamber body may include flowing an etchant into the chamber body to etch an interior of the chamber body, e.g., flowing the etchant 210 into the chamber body 160 to etch the interior of the chamber body (shown in FIG. 5), as shown with box 316 and box 318. Opening the gate valve to load 302 the substrate into the chamber body may include flowing a material layer precursor into the chamber to form a precoating on a substrate support, e.g., flowing the material layer precursor 208 into the chamber body 160 to form a precoating on the substrate support 116 (shown in FIG. 5), as shown with box 320 and box 322. Opening the gate valve to load 302 the substrate into the chamber body may include heating the substrate using a predetermined fixed power value, e.g., heating the substrate 2 using the predetermined fixed power value applied to the upper heater element array 166 and the lower heater element array 168 (shown in FIG. 6), as shown with box 324. It is contemplated that either (or both) the flow of etchant into the chamber body and the flow of material layer precursor to form a precoating may occur simultaneously with the movement of the plurality of lift pins between the first position and the second position, e.g., the flow of etchant 210 and the flow of material layer precursor 208 into the chamber body 160 simultaneously with the movement of the plurality of lift pins 120 between the first position 202 and the second position 204 (shown in FIG. 5), as shown with box 314. It is contemplated that the heating of the substrate and chamber body by the upper heating element array and the lower heating element array may occur following the movement of the plurality of lift pins between the first position and the second position, as well as the flow of the etchant and the material layer precursor. In other examples it is contemplated that the heating of the substrate and the chamber body by the upper heating element array and the lower heating element array may occur prior to the movement of the plurality of lift pins between the first position and the second position, the flow of the etchant, and the flow of the material layer precursor.

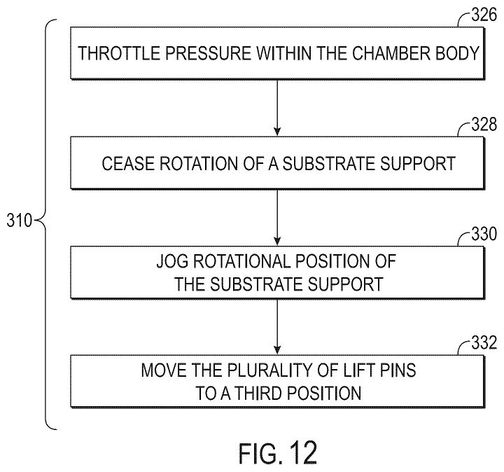

As shown in FIG. 12, opening the gate valve to unload 310 the substrate with the material layer deposited thereon may include one or more unload operation being executed prior to unloading the substrate from the chamber body, e.g., the operations of FIGS. 7-9, as shown with bracket 310. Instructions recorded on the plurality of program modules 132 may cause the throttling of the pressure within the chamber body prior to opening the gate valve, e.g., throttling the pressure within the chamber body 160 from the predetermined deposition value to the predetermined unload value prior to opening the gate valve 118 (shown in FIG. 8), as shown with box 326. Instructions recorded on the controller may cause the ceasing rotation of the substrate support and jogging the substrate support, e.g., ceasing the rotation R of the substrate support 116 and jogging J the substrate support 116 via the shaft member 182 and support member 180 (as shown in FIG. 8), as shown with box 328 and box 330. It is contemplated that the jogging J of the substrate support may occur to orientate the plurality of lift pins to a lift pin actuation rotational position. Once the plurality of lift pins are orientated in the lift pin actuation rotation position the instructions recorded on the controller may cause the plurality of lift pins to move between the first position and the third position, e.g., the plurality of lift pins 120 moving between the first position 202 and the third position 206 (shown in FIG. 8), as shown with box 332.

Although shown and described herein in the context of a single substrate transfer robot couples to single process chamber, it is to be understood and appreciated that the semiconductor processing systems employing two or more substrate transfer robots and/or two or more process chambers may also benefit from the present disclosure. For example, in certain examples the substrate transfer robot maybe a back-end substrate transfer robot of a semiconductor processing system including a cluster-type platform, and the process module may be one of a plurality of process modules hosted by the cluster-type platform. Examples of suitable cluster-type semiconductor processing systems include those shown and described in U.S. Patent Application Publication No. 2024/0178019A1 to Deshpande et al., file don Nov. 28, 2023, the contents of which is incorporated herein by reference in its entirety. Advantageously, employment of the systems and methods shown and described herein may increase the throughput of semiconductor processing systems employed for material layer deposition by between about 10% and about 60%, or between about 20% and about 60%, or even between about 30% and about 60% relative to a similarly configured semiconductor processing system employed for a common material layer deposition process and not employing one or more of the systems and methods shown and described herein.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A semiconductor processing system, comprising:
a chamber body;
a gate valve abutting the chamber body;
a controller operably connected to the gate valve and responsive to instructions recorded on a memory to:
open the gate valve to load a substrate into the chamber body;
close the gate valve to deposit a material layer onto the loaded substrate; and
open the gate valve to unload the substrate with the material layer deposited thereon,
wherein (a) one or more load operation to load the substrate into the chamber body is executed prior to loading the substrate into the chamber body, or (b) one or more unload operation to unload the substrate with the material layer deposited thereon is executed prior to unloading the substrate from the chamber body.

2. The system of claim 1, further comprising:
a substrate support arranged within the chamber body;
a plurality of lift pins slidably received within the substrate support and movable between a first position, wherein the plurality of lift pins dangle below the substrate support, and a second position, wherein the plurality of lift pins protrude above the substrate support, the plurality of lift pins operably associated with the controller; and
wherein the instructions recorded on the memory further cause the controller to move the plurality of lift pins between the first position and the second position prior to opening the gate valve to load the substrate into the chamber body.

3. The system of claim 2, wherein, simultaneously with moving the plurality of lift pins between the first position and the second position, the instructions recorded on the memory further cause the controller to:
flow an etchant into the chamber body; and
etch an interior of the chamber body using the etchant prior to the load of the substrate into the chamber body.

4. The system of claim 2, wherein, simultaneously with moving the plurality of lift pins between the first position and the second position, the instructions recorded on the memory further cause the controller to:
flow a material layer precursor into the chamber body; and
form a precoating onto the substrate support arranged within the chamber body prior to the load of the substrate into the chamber body.

5. The system of claim 1, further comprising an array of heating elements supported outside the chamber body and operably associated with the controller, and wherein the instructions further cause the controller to heat the substrate using a predetermined fixed power value during the load of the substrate into the chamber body.

6. The system of claim 1, wherein the instructions further cause the controller to throttle pressure within the chamber body from a predetermined deposition pressure value to a predetermined unload pressure value prior to opening the gate valve to unload the substrate with the material layer deposited thereon.

7. The system of claim 6, wherein the predetermined unload pressure value is less than pressure within a substrate transfer chamber coupled by the gate valve to the chamber body.

8. The system of claim 6, further comprising simultaneously with the throttling of the pressure within the chamber body, cease rotation of a substrate support arranged within the chamber body and upon which the substrate is seated during deposition of the material layer thereon.

9. The system of claim 6, further comprising simultaneously with the throttling the pressure within the chamber body, jog rotational position of a substrate support arranged within the chamber body and upon which the substrate is seated during deposition of the material layer thereon to a lift pin actuation rotational position.

10. The system of claim 6, further comprising:
a substrate support arranged within the chamber body;
a plurality of lift pins slidably received within the substrate support and movable between a first position, wherein the plurality of lift pins dangle below the substrate support, and a second position, wherein the plurality of lift pins protrude above the substrate support, a third position separated from the first position by the second position, the plurality of lift pins operably associated with the controller; and
wherein the instructions recorded on the memory further cause the controller to move the plurality of lift pins between the first position and the third position simultaneously with throttling of the pressure within the chamber body from the predetermined deposition pressure value to the predetermined unload pressure value.

11. A substrate processing method, comprising:
at a semiconductor processing system including a chamber body, a gate valve abutting the chamber body, and a controller operably connected to the gate valve;
opening the gate valve to load a substrate into the chamber body;
closing the gate valve to deposit a material layer onto the loaded substrate; and
opening the gate valve to unload the substrate with the material layer deposited thereon.

12. The substrate processing method of claim 11, further comprising:
a substrate support arranged within the chamber body; and
a plurality of lift pins slidably received within the substrate support and movable between a first position, wherein the plurality of lift pins dangle below the substrate support, and a second position, wherein the plurality of lift pins protrude above the substrate support;
moving the plurality of lift pins between the first position and the second position prior to opening the gate valve to load the substrate into the chamber body.

13. The substrate processing method of claim 12, further comprising:
simultaneously with the moving the plurality of lift pins between the first position and the second position, flowing an etchant into the chamber body;
etching an interior of the chamber body using the etchant prior to the loading of the substrate into the chamber body;
flowing a material layer precursor into the chamber body; and
forming a precoating onto the substrate support prior to the loading of the substrate into the chamber body.

14. The substrate processing method of claim 11, further comprising:
an array of heating elements supported outside the chamber body;
heating the substrate using a predetermined fixed power value during the loading of the substrate into the chamber body.

15. The substrate processing method of claim 11, further comprising throttling pressure within the chamber body from a predetermined deposition pressure value to a predetermined unload pressure value prior to the opening of the gate valve to unload the substrate with the material layer deposited thereon.

16. The substrate processing method of claim 15, further comprising:
a substrate support arranged within the chamber body;
ceasing rotation of the substrate support and upon which the substrate is seated during deposition of the material layer thereon.

17. The substrate processing method of claim 15, further comprising:
a substrate support arranged within the chamber body;
jogging rotational position of the substrate support and upon which the substrate is seated during deposition of the material layer thereon to a lift pin actuation rotational position.

18. The substrate processing method of claim 15, further comprising:
a substrate support arranged within the chamber body; and
a plurality of lift pins slidably received within the substrate support and movable between a first position, wherein the plurality of lift pins dangle below the substrate support, and a second position, wherein the plurality of lift pins protrude above the substrate support,
wherein the plurality of lift pins have a third position, the third position separated from the first position by the second position, the method further comprising moving the plurality of lift pins to the third position simultaneously with the throttling of the pressure within the chamber body from the predetermined deposition pressure value to the predetermined unload pressure value.

19. The substrate processing method of claim 11, further comprising:
a substrate support arranged within the chamber body;
a plurality of lift pins slidably received within the substrate support and movable between a first position, wherein the plurality of lift pins dangle below the substrate support, and a second position, wherein the plurality of lift pins protrude above the substrate support, a third position separated from the first position by the second position;
throttling pressure within the chamber body from a predetermined deposition pressure value to a predetermined unload pressure value prior to opening the gate valve to unload the substrate with the material layer deposited thereon;
ceasing rotation of the substrate support arranged within the chamber body and upon which the substrate is seated during the deposition of the material layer thereon;
jogging rotational position of the substrate support arranged within the chamber body and upon which the substrate is seated during the deposition of the material layer thereon to a lift pin actuation rotational position; and
moving the plurality of lift pins to the third position, wherein the second position is between the first position and the third position.

20. A computer program product, comprising:
a non-transitory machine-readable medium having a plurality of program modules recorded on the medium, that when read by a controller, cause the controller to:
open a gate valve abutting a chamber body operably associated with the controller to load a substrate into the chamber body;
close, using the controller, the gate valve to deposit a material layer onto the substrate; and
open, using the controller, the gate valve to unload the substrate with the material layer deposited thereon,
wherein (a) one or more load operation to load the substrate into the chamber body is executed prior to loading the substrate into the chamber body, or (b) one or more unload operation to unload the substrate with the material layer deposited thereon is executed prior to unloading the substrate from the chamber body.
